(19) United States
(12) Patent Application Publication
(10) Pub. No.: US 2023/0295500 A1
(43) Pub. Date: Sep. 21, 2023

(54) ETCHANT COMPOSITION FOR ADJUSTING ETCHING SELECTIVITY OF TITANIUM NITRIDE FILM WITH RESPECT TO TUNGSTEN FILM, AND ETCHING METHOD USING SAME

(71) Applicant: YOUNG CHANG CHEMICAL CO., LTD, Seongju-gun, Gyeongsangbuk-do (KR)

(72) Inventors: Seung Hun LEE, Daegu (KR); Seung Hyun LEE, Daegu (KR); Seong Hwan KIM, Daegu (KR); Seung Oh JIN, Daegu (KR)

(21) Appl. No.: 18/016,725

(22) PCT Filed: Jul. 5, 2021
(86) PCT No.: PCT/KR2021/008475

§ 371 Date: Jan. 18, 2023

(30) Foreign Application Priority Data
Aug. 4, 2020 (KR) 10-2020-0097214

(51) Int. Cl. C09K 13/06

(52) U.S. Cl. CPC C09K 13/06

(57) ABSTRACT

Proposed is an etching composition capable of adjusting an etching selectivity of a tungsten film with respect to a tungsten film. An etching method using the same etching composition is also proposed. The etching composition includes an inorganic acid, an oxidizing agent, an additive represented by Formula 1, and the remaining proportion of water. The etching composition exhibits remarkable effects of providing a high etching rate for a titanium nitride film and of adjusting the etching selectivity of a titanium nitride film with respect to a tungsten film to be in a range of 1 to 15.

### TECHNICAL FIELD

The present invention relates to a composition capable of adjusting an etching selectivity of a nitride metal film with respect to a metal film in a semiconductor device manufacturing process and to an etching method using the composition. More particularly, the present invention relates to an etchant composition capable of adjusting an etching selectivity of a titanium nitride film with respect to a tungsten film and an etching method using the composition.

### BACKGROUND ART

In the process of manufacturing a semiconductor device, a tungsten film is used to form gate electrodes, interconnects, and bather layers and to fill contact holes or via holes in thin film transistors of semiconductor devices and liquid crystal displays.

A titanium nitride film is used as an underlying layer or a capping layer for a noble metal, aluminum, or copper wiring in printed circuit boards (PCBs), semiconductor devices, and liquid crystal displays. Alternatively, the titanium nitride film is used as a barrier metal or a gate metal.

A tungsten film is widely used as a conductive metal in the process of manufacturing semiconductor devices. However, the tungsten film has poor adhesion with other films such as silicon films and silicon oxide films. Therefore, the titanium nitride film is typically used as a protective film for the tungsten film.

In the process of manufacturing semiconductor devices, dry etching and wet etching are often used to remove tungsten and titanium nitride films. Sometimes, a chemical mechanical polishing (CMP) process is also used to remove tungsten films. In the process of etching a specific portion of a titanium nitride film and a portion of a tungsten film at the same time, in the case of using dry etching, it is difficult to control etching selectivity to etch the titanium nitride film and the tungsten film the same rate or at different rates. Therefore, a wet etching process is used to control the etching selectivity, and an etchant having a suitable composition is required for the wet etching process.

Korean Patent Application Publication No. 10-2015-050278 discloses an etchant composition for etching a stack of a titanium nitride film and a tungsten film. When the etchant composition is used, the etching selectivity of a titanium nitride film with respect to a tungsten film is 1. The etchant composition is for use in a high-temperature, long-time batch process.

However, the wet etching process in the process of manufacturing semiconductor devices has recently been changed from a batch type process to a single-type process which is advantageous in terms of preventing re-pollution by particles during the etching process and of reducing a processing time to several minutes as compared to the batch type which typically takes several tens of minutes.

With the trend of adopting the single type etching process, an etchant that enables a titanium nitride film to be more rapidly etched than a tungsten film is required. That is, an etchant exhibiting a high etching selectivity of the titanium nitride film with respect to the tungsten film needs to be developed.

On the other hand, the required etching selectivity between a titanium nitride film and a tungsten film may vary depending on the types of memory devices. In the case of NAND flash memories, an etchant enabling a tungsten film and a titanium nitride film to be etched at an equal etching rate is used. That is, an etching with an etching selectivity of 1 is required. However, in the case of dynamic random access memories (DRAMs), a titanium nitride film needs to be etched at a higher etching rate than a tungsten film. That is, the etching selectivity of the titanium nitride film with respect to the tungsten film needs to be increased. For this reason, it is necessary to develop an etchant composition enabling the control of the etching selectivity of the titanium nitride film with respect to the tungsten film such that the etching selectivity becomes 1 or higher.

### DISCLOSURE

### Technical Problem

The present invention has been made in view of the problems occurring in the related art and an objective of the present invention is to provide an etchant composition capable of increasing an etching rate for a titanium nitride film and capable of controlling an etching selectivity of the titanium nitride film to a tungsten film to be 1 or higher in various single-type wet etching processes.

Another objective of the present invention is to provide an etching method using the etchant.

### Technical Solution

In one aspect, the present invention provides an etchant composition including an inorganic acid, an oxidizing agent, an additive represented by Formula 1, and a residual amount of water, in which the etchant composition enables a titanium nitride film to be etched at a significantly high etching rate and enables an etching selectivity of the titanium nitride film with respect to a tungsten film to be adjusted to be 1 or higher.

The inorganic acid included in the etchant composition of the present invention may be any one selected from the group consisting of sulfuric acid, phosphoric acid, and mixtures thereof and may serve as an etching promoter.

The content of the inorganic acid may be in a range of 81% to 95% by weight with respect to the total weight of the etchant composition.

The oxidizing agent included in the etchant composition of the present invention may be any one selected from the group consisting of hydrogen peroxide, nitric acid, tert-butylhydroperoxide, and 2-butaneperoxide.

The content of the oxidizing agent may be in a range of 0.1% to 3% by weight with respect to the total weight of the etchant composition.

The additive included in the etchant composition of the present invention may be represented by Formula 1. The additive may include an alkylammonium salt including a cationic surfactant or an alkyl alcohol ammonium salt including a cationic surfactant, and an alkyl sulfate salt including an anionic surfactant.

The content of the additive represented by Formula 1 may be in a range of 20 to 500 ppm by weight with respect to the total weight of the etchant composition.

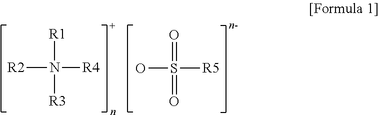

In Formula 1, R1, R2, R3, and R4 may be each independently a hydrogen atom, an alkyl group having 1 to 18 carbon atoms, a benzylalkyl group having 1 to 20 carbon atoms, or an alkyl alcohol group having 1 to 6 carbon atoms, and R5 is a 1/2 oxygen atom, a hydroxy group, or an alkyl group having 1 to 16 carbon atoms. n is an integer in a range of from 1 to 2.

As to the etchant composition, components included in the composition and a composition ratio of the included components may be adjusted to enable a titanium nitride film to be etched at a high etching rate and to adjust an etching selectivity of the titanium nitride film to a tungsten film. Specifically, the structure of cations and anions of the additive represented by Formula 1 is adjustable. The adjustment makes the etching selectivity of the titanium nitride film to the tungsten film fell in a range of 1 to 15, which means that an etching amount of the titanium nitride film: an etching amount of the tungsten film is in a range of 1:1 to 15:1.

An etching process using the etchant composition may be performed in a temperature range of 50° C. to 90° C. To increase the stability of the etching process, the inorganic acid and the remaining components may be mixed and used in an etching facility. When the inorganic acid and the remaining components are mixed outside the facility, the inorganic acid and the remaining components may be mixed immediately before being used in the etching process.

### Advantageous Effects

In the process of wet etching a titanium nitride film and a tungsten film, the etchant composition according to the present invention has the effects of etching the titanium nitride film at a high etching rate and of adjusting the etching rates such that the etching rate for the titanium nitride film is equal to or up to 15 times higher than the etching rate of the tungsten film. In addition, the etchant composition exhibits a high etching selectivity for the titanium nitride film with respect to an underlying layer such as a polysilicon film or a silicon oxide film. Therefore, the etchant composition can be widely used in semiconductor device manufacturing processes and can solve etching-related problems such as particle adhesion to an oxide surface and generation of residue during nitride removal.

### BEST MODE

Hereinafter, the present disclosure will be described in detail.

In one aspect, the present invention provides an etchant composition including an inorganic acid, an oxidizing agent, an additive represented by Formula 1, and water. The etchant composition enables a titanium nitride film to be etched at a significantly high etching rate and enables an etching selectivity for the titanium nitride film with respect to a tungsten film to be adjusted in a range of 1 to 15.

The inorganic acid serves as an etching promoter and is any one selected from the group consisting of sulfuric acid, phosphoric acid, and a mixture thereof. The content of the inorganic acid is 81% to 95% by weight with respect to the total weight of the etchant composition.

When the content of the inorganic acid is lower than 81% by weight, the etching rate of the tungsten film is excessively high. When the content of the inorganic acid is higher than 95% by weight, both the etching rate of the titanium nitride film and the etching rate of the tungsten film are excessively slow. Specifically, the reduction in the etching rate of the titanium nitride film is more problematic. Therefore, the content of the inorganic acid needs to fall within a range of 81% to 95% by weight with respect to the total weight of the etchant composition.

In addition, the oxidizing agent is any one selected from the group consisting of hydrogen peroxide, nitric acid, tert-butylhydroperoxide, and 2-butaneperoxide, and the content of the oxidizing agent falls in a range of 0.1% to 3% by weight with respect to the total weight of the etchant composition.

When the content of the oxidizing agent is lower than 0.1% by weight, the etching rate of the titanium nitride film and the etching rate of the tungsten film are excessively slow. Specifically, the reduction in the etching rate of the titanium nitride film is more problematic. When the content of the oxidizing agent is higher than 3% by weight, the etching rate of the tungsten film is excessively high. Therefore, the content of the oxidizing agent needs to fall within a range of 0.1% to 3% by weight with respect to the total weight of the etchant composition.

The additive is represented by Formula 1. The additive may include an alkylammonium salt including a cationic surfactant or an alkyl alcohol ammonium salt including a cationic surfactant, and an alkyl sulfate salt including an anionic surfactant.

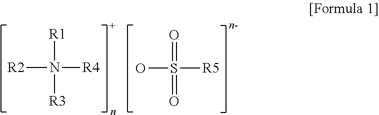

The additive may be any one selected from the group consisting of tetramethylammonium methylsulfate, tributylmethylammonium methylsulfate, dodecyltrimethylammonium methylsulfate, docosyltrimethylammonium methylsulfate, hexadecyltrimethylammonium methylsulfate, triisonononylmethylammonium methylsulfate, heptadecyltrimethylammonium methylsulfate, trimethyloctadecylammonium methylsulfate, dimethyldiisooctadecylammonium methylsulfate, butylisooctylmethylammonium methylsulfate, tris-2-hydroxyethyl ammonium methylsulfate, ammonium sulfate, tetramethylammonium hydrosulfate, diethylammonium sulfate, ethylenediammonium sulfate, tetraethylammonium hydrosulfate, triethylammonium sulfate, tetrabutylammonium sulfate, tetrabutylammonium hydrosulfate, methylsulfate, trimethylammonium pentadecylsulfate, ammonium laurylsulfate, ammonium isosulfate, docylisoethylammonium methylsulfate, trisoethylammonium methylsulfate, trisoethylammonium methylsulfate, trisoethylammonium methylsulfate, trisoethylammonium methylsulfate, tetramethylammonium hydrosulfate, ethylenediammonium hydrosulfate, ethylenediammonium hydrosulfate, ethylenediammonium disulfate, dodecylenediammonium oxylsulfate, ethylenediethylammonium oxylsulfate, dodecylsulfate, ethylenediethylammonium oxylsulfate, ethylenediethylenediammonium oxysulfate, dodecylsulfate, ethylenediethylammonium oxylsulfate, dodecylsulfate, ethylenediammonium oxylsulfate, and mixtures thereof. In this case, the content of the additive represented by Formula 1 falls within a range of 20 to 500 ppm by weight (i.e., a range of 0.002% to 0.05% by weight) with respect to the total weight of the etchant composition.

When the content of the additive is lower than 20 ppm (i.e., 0.002% by weight), the etching rate of the tungsten film increases, and thus the etching of the tungsten film is faster than the etching of the titanium nitride film, which means that the etching selectivity of the titanium nitride film with respect to the tungsten film becomes less than 1. When the content of the additive is equal to or higher than 500 ppm (i.e., 0.05% by weight), both the etching rate of both the tungsten film and the etching rate of the titanium nitride film are reduced. Specifically, the reduction in the etching rate of the titanium nitride is more problematic. Therefore, the content of the additive needs to fall within a range of 20 to 500 ppm (i.e., 0.002% to 0.05% by weight) with respect to the total weight of the etchant composition.

As to the etchant composition, to control the etching selectivity for a titanium nitride film with respect to a tungsten film, which is required in an etching process, the structure of cations and anions of the additive represented by Formula 1 may be adjusted. Thus, the etching selectivity for the titanium nitride film with respect to the tungsten film may be adjusted to fall within a range of 1 to 15, which means that an etching amount of the titanium nitride film:an etching amount of the tungsten film is in a range of 1:1 to 15:1. In general, when the size of the cation is large, the etching selectivity of the titanium nitride film with the tungsten film rises to a value greater than or equal to 1, and when the size of the anion is large, the etching selectivity of the titanium nitride film with respect to the tungsten film is about 1.

The etchant composition according to the present invention preferably includes 81% to 95% by weight of an inorganic acid, 0.1% to 3% by weight of an oxidizing agent, 0.002% to 0.05% by weight of an additive represented by Formula, and a residual amount of water.

Preferably, the etchant composition may be used in an etching process performed in a process temperature range of 50° C. to 90° C.

When using the etchant composition in the etching process performed in the temperature range of 50° C. to 90° C., to increase the stability of the etching process, the inorganic acid and the remaining components may be mixed in an etching facility. When the inorganic acid and the remaining components are mixed outside the etching facility, the inorganic acid and the remaining components may be mixed immediately before being used for the etching process.

In addition, the process of simultaneously etching the titanium nitride film and the tungsten film, using the etchant composition according to the present invention, may be performed according to a method known to the ordinarily skilled in the art. For example, a batch-type method may be used in which all of the substrates to be processed are immersed in the etchant composition. Alternatively, a single-type method may be used in which the etchant composition is sprayed onto the substrates, one after another. During the etching process, the temperature of the etchant may vary to match with other processes or depending on other factors. Preferably, the temperature of the etchant is set to fall within a range of 50° C. to 90° C.

In addition, a method of etching a titanium nitride film and a tungsten film using the etchant composition of the present invention may be applied to a method of manufacturing electronic devices. The substrate may be a semiconductor wafer. However, the present invention is not limited thereto, and any substrate commonly used in the art can be used. The titanium nitride film and the tungsten film deposited on the substrate may be formed by a conventional method.

Hereinbelow, the present invention will be described in more detail with reference to examples, comparative examples, and experimental examples. The examples, comparative examples, experimental examples, and comparative experimental examples described below are presented only for the illustrative purposes, and thus the present invention is not limited to the following comparative examples, experimental examples, and comparative experimental examples and may be changed, modified, and altered in various forms.

### MODE FOR CARRYING OUT THE INVENTION

### Examples 1 and 25 and Comparative Examples 1 to 12

To prepare etchant compositions of examples and comparative examples, the components for each composition were added to an experimental beaker equipped with a magnetic bar, according to the corresponding composition ratio shown in Table 1, and the beakers were sealed. Next, the content in each beaker was stirred at room temperature at 400 rpm for 30 minutes at room temperature to prepare the compositions of the examples and comparative examples.

TABLE 1

| | Inorganic acid | | Oxidizing agent | | Additive | | | |
|---|---|---|---|---|---|---|---|---|
| | | Content (% | | Content (% | | Content (% | Water | |
| Classification | Component | by weight) | Component | by weight) | Component | by weight) | Component | Content |
| Example 1 | A-1 | 89 | B-1 | 1 | C-1 | 0.01 | D-1 | Balance |
| Example 2 | A-1 | 95 | B-1 | 0.3 | C-1 | 0.01 | D-1 | Balance |
| Example 3 | A-1 | 81 | B-1 | 3 | C-1 | 0.01 | D-1 | Balance |
| Example 4 | A-2 | 84 | B-1 | 0.3 | C-1 | 0.01 | D-1 | Balance |
| Example 5 | A-2 | 81 | B-1 | 1 | C-1 | 0.01 | D-1 | Balance |
| Example 6 | A-1 | 89 | B-2 | 2 | C-1 | 0.01 | D-1 | Balance |
| Example 7 | A-1 | 89 | B-3 | 0.1 | C-1 | 0.01 | D-1 | Balance |
| Example 8 | A-1 | 89 | B-4 | 0.1 | C-1 | 0.01 | D-1 | Balance |
| Example 9 | A-2 | 81 | B-2 | 2 | C-1 | 0.01 | D-1 | Balance |
| Example 10 | A-1 | 89 | B-1 | 2 | C-3 | 0.003 | D-1 | Balance |
| Example 11 | A-1 | 89 | B-1 | 2 | C-3 | 0.05 | D-1 | Balance |
| Example 12 | A-1 | 89 | B-1 | 2 | C-3 | 0.002 | D-1 | Balance |
| Example 13 | A-1 | 89 | B-1 | 2 | C-4 | 0.05 | D-1 | Balance |
| Example 14 | A-1 | 89 | B-1 | 2 | C-6 | 0.05 | D-1 | Balance |
| Example 15 | A-1 | 89 | B-1 | 2 | C-2 | 0.01 | D-1 | Balance |
| Example 16 | A-1 | 89 | B-1 | 2 | C-3 | 0.01 | D-1 | Balance |
| Example 17 | A-1 | 89 | B-1 | 2 | C-4 | 0.01 | D-1 | Balance |
| Example 18 | A-1 | 89 | B-1 | 2 | C-5 | 0.01 | D-1 | Balance |
| Example 19 | A-1 | 89 | B-1 | 2 | C-6 | 0.01 | D-1 | Balance |
| Example 20 | A-1 | 89 | B-1 | 2 | C-7 | 0.01 | D-1 | Balance |
| Example 21 | A-1 | 89 | B-1 | 2 | C-8 | 0.02 | D-1 | Balance |
| Example 22 | A-2 | 82 | B-1 | 2 | C-5 | 0.01 | D-1 | Balance |
| Example 23 | A-2 | 82 | B-1 | 2 | C-6 | 0.01 | D-1 | Balance |
| Example 24 | A-2 | 82 | B-1 | 2 | C-7 | 0.01 | D-1 | Balance |
| Example 25 | A-2 | 82 | B-1 | 2 | C-8 | 0.01 | D-1 | Balance |
| Comparative | A-1 | 81 | B-1 | 6 | — | — | D-1 | Balance |
| Example 1 | | | | | | | | |
| Comparative | A-1 | 79 | B-1 | 2 | — | — | D-1 | Balance |
| Example 2 | | | | | | | | |
| Comparative | A-2 | 79 | B-1 | 2 | — | — | D-1 | Balance |
| Example 3 | | | | | | | | |
| Comparative | A-2 | 89 | B-1 | 2 | — | — | D-1 | Balance |
| Example 4 | | | | | | | | |
| Comparative | A-1 | 96 | B-1 | 0.05 | C-1 | 0.01 | D-1 | Balance |
| Example 5 | | | | | | | | |
| Comparative | A-1 | 92 | B-1 | 0.05 | — | — | D-1 | Balance |
| Example 6 | | | | | | | | |
| Comparative | A-1 | 96 | — | — | — | — | D-1 | Balance |
| Example 7 | | | | | | | | |
| Comparative | A-1 | 89 | B-1 | 2 | C-9 | 0.01 | D-1 | Balance |
| Example 8 | | | | | | | | |
| Comparative | A-1 | 89 | B-1 | 2 | C-10 | 0.01 | D-1 | Balance |
| Example 9 | | | | | | | | |
| Comparative | A-1 | 89 | B-1 | 2 | C-1 | 0.001 | D-1 | Balance |
| Example 10 | | | | | | | | |
| Comparative | A-1 | 89 | B-1 | 2 | C-1 | 0.06 | D-1 | Balance |
| Example 11 | | | | | | | | |
| Comparative | A-2 | 70 | B-2 | 5 | — | — | D-1 | Balance |
| Example 12 | | | | | | | | |

A-1: Sulfuric acid
A-2: Phosphoric acid
B-1: Hydrogen peroxide
B-2: Nitric acid
B-3: Tert-butylhydroperoxide
B-4: 2-butane peroxide
C-1: Tetramethylammonium sulfate
C-2: Ethylenediamineammonium sulfate
C-3: Ammonium methylsulfate
C-4: Dodecyltrimethylammonium Sulphate
C-5: Ammonium lauryl sulfate
C-6: Diethylammonium octyl sulfate
C-7: Ammonium sulphate
C-8: 2-hydroxyethylammonium dodecylsulfate
C-9: Ammonium phosphate
C-10: Ammonium acetate
D-1: Deionized water

### Experimental Example and Comparative Experimental Example

### Measuring Etching Rates of Titanium Nitride Film and Tungsten Film

The performance of each of the etchants prepared in Examples 1 to 25 and Comparative Examples 1 to 12 was measured. The results are shown in Table 2 and denoted by Experimental Examples 1 to 25 and Comparative Experimental Examples 1 to 12.

First, for the measurement, a titanium nitride film and a tungsten film were deposited on a plurality of wafers by chemical vapor deposition (CVD) under the same conditions as in actual semiconductor device manufacturing process.

Before starting etching, the initial thickness of each film was measured using a scanning electron microscope (SEM). Next, for each of the etchants, the wafers with the titanium nitride film and the tungsten film formed thereon were immersed in the etchant having a temperature of 80° C. in a quartz stirrer rotating at 500 rpm, and etching was performed for 30 seconds.

After the etching was completed, the wafers were washed with ultra-pure water and dried with a drier so that the remaining etchant and moisture were completely removed.

The thickness of each of the films remaining after the etching was measured using a scanning electron microscope. The difference in the thickness of each of the thin films before and after the etching was calculated to determine the etching amount of each of the titanium nitride film and the tungsten film for 30 seconds at a given temperature.

TABLE 2

| | Etching amount | | |
|---|---|---|---|
| | TiN | W | Etching |
| | (Å/ | (Å/ | selectivity |
| Classification | min.) | min.) | TiN/W |
| Experimental Example 1 | 76 | 9 | 8.4 |
| Experimental Example 2 | 45 | 4 | 11.3 |
| Experimental Example 3 | 84 | 15 | 5.6 |
| Experimental Example 4 | 53 | 8 | 6.6 |
| Experimental Example 5 | 82 | 8 | 10.3 |
| Experimental Example 6 | 54 | 6 | 10.7 |
| Experimental Example 7 | 45 | 4 | 11.3 |
| Experimental Example 8 | 43 | 5 | 8.6 |
| Experimental Example 9 | 48. | 7 | 6.9 |
| Experimental Example 10 | 90 | 18 | 5 |
| Experimental Example 11 | 68 | 9 | 7.6 |
| Experimental Example 12 | 94 | 25 | 3.8 |
| Experimental Example 13 | 58 | 4 | 14.5 |
| Experimental Example 14 | 41 | 40 | 1.0 |
| Experimental Example 15 | 79 | 12 | 6.6 |
| Experimental Example 16 | 82 | 12 | 6.8 |
| Experimental Example 17 | 70 | 6 | 11.7 |
| Experimental Example 18 | 46 | 27 | 1.7 |
| Experimental Example 19 | 48. | 32 | 1.5 |
| Experimental Example 20 | 72 | 16 | 4.5 |
| Experimental Example 21 | 56 | 11 | 5.1 |
| Experimental Example 22 | 40 | 24 | 1.7 |
| Experimental Example 23 | 41 | 25 | 1.6 |
| Experimental Example 24 | 60 | 12 | 5.0 |
| Experimental Example 25 | 50 | 9 | 5.6 |
| Comparative Experimental Example 1 | 105 | 131 | 0.8 |
| Comparative Experimental Example 2 | 57 | 75 | 0.76 |
| Comparative Experimental Example 3 | 45 | 65 | 0.69 |
| Comparative Experimental Example 4 | 54 | 76 | 0.71 |
| Comparative Experimental Example 5 | 18 | 10 | 1.8 |
| Comparative Experimental Example 6 | 15 | 23 | 0.65 |
| Comparative Experimental Example 7 | 2 | 2 | 1.0 |
| Comparative Experimental Example 8 | 150 | 240 | 0.63 |
| Comparative Experimental Example 9 | 124 | 184 | 0.67 |
| Comparative Experimental Example 10 | 95 | 113 | 0.84 |
| Comparative Experimental Example 11 | 16 | 8 | 2.0 |
| Comparative Experimental Example 12 | 23 | 32 | 0.72 |

As shown in Table 2, the amount of the titanium nitride film etched at 80° C. for 30 seconds is higher was the amount of the tungsten film etched under the same conditions for each of the etchants used in Experimental Examples 1 to 25. That is, these etchants exhibited a significant effect of increasing the etching selectivity of the titanium nitride film with respect to the tungsten film. The etching selectivity for each etchant was in a range of 1 to 15 (i.e., the amount of the titanium nitride film etched to the amount of the tungsten film etched=1:1 to 15:1). In addition, the amount of the titanium nitride film etched was large, indicating a significantly high etching rate of the tungsten nitride film.

In contrast with the results of the experimental examples, the results of Comparative Experimental Examples 1, 2, 3, 4, 6, 8, 9,10, and 12 showed that the etching amount of the titanium nitride film at 80° C. was less than the etching amount of the tungsten film. That is, the etching selectivity was less than 1, and thus the etchants that exhibited the results were determined to be unsuitable for use in the intended etching process.

In addition, in the case of Comparative Experimental Examples 5, 7, and 11, the etching selectivity was higher than 1, but both of the respective etching amounts of the two films were not sufficient. That is, the etching rates of the two films were excessively low, resulting in a longer process time. Therefore, the etchants used in these comparative experimental examples were not suitable for use in the intended etching process.

That is, the selectivity was 1.8:1 in Comparative Experiment Example 5, the selectivity was 1:1 in Comparative Experiment Example 7, the selectivity was 2:1 in Comparative Experiment Example 11. That is, when considering only the etching selectivity, the etchants used were suitable. However, the etching amounts of the titanium nitride film (TiN) were 18, 2, and 16 which are significantly small in Comparative Experimental Examples 5, 7, and 11, respectively. That is, since the etching rates were excessively low and thus the processing times were long, the etchants used in Comparative Experimental Examples 5, 7, and 11 were unsuitable.

A comprehensively view for Examples 1 to 25 and Comparative Examples 1 to 12 on the basis of the results of the experimental examples and the comparative experimental examples provides conclusions described below. First, in the case of using each of the etchants of Examples 1 to 25, the etching rate of the titanium nitride film was significantly higher than the etching rate of the tungsten film, indicating that the etching of the titanium nitride was faster than the etching of the tungsten film. In addition, the etching selectivity of the titanium nitride film with respect to the tungsten film was adjustable within a range of 1 to 15 (the etching amount of the titanium nitride film to the etching amount of the tungsten film etching amount=1:1 to 15:1). Second, the respective etching rates of the titanium nitride film and the tungsten film were remarkably high, indicating that the etching was fast for both of the titanium nitride film and the tungsten film.

In addition, the results of the experiments conducted vary varying temperatures ranging from 50° C. to 90° C. were almost the same as the results of the experiments conducted at 80° C.

The etchant compositions according to the examples of the present invention include 81% to 95% by weight of an inorganic acid, 0.1% to 3% by weight of an oxidizing agent, 0.002% to 0.05% by weight of an additive represented by Formula 1, and the remaining proportion of water. These etchant compositions are verified to exhibit a remarkable effect in which an etching rate for a titanium nitride film is sufficiently high, and an etching selectivity of a titanium nitride film with respect to a tungsten film can be adjusted in a range of 1 to 15 (an etching amount of a titanium nitride film to an etching amount of a tungsten film=1:1 to 15:1) depending on various wet etching conditions for a semiconductor device manufacturing method.

Specific parts of the present disclosure have been described in detail, and those who ordinarily skilled in the art will appreciate that the specific parts described are only for illustrative purposes and the scope of the present invention is not limited by the specific parts described above. Thus, the substantial scope of the present disclosure will be defined by the appended claims and their equivalents.

1. An etchant composition comprising:
a) an inorganic acid;
b) an oxidizing agent;
c) an additive represented by Formula 1; and
d) water as a balance. 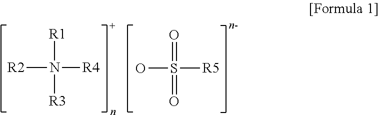
(In Formula 1, R1, R2, R3, and R4 is each independently a hydrogen atom, an alkyl group having 1 to 18 carbon atoms, a benzylalkyl group having 1 to 20 carbon atoms, or an alkyl alcohol group having 1 to 6 carbon atoms, and R5 is a 1/2 oxygen atom, a hydroxy group, or an alkyl group having 1 to 16 carbon atoms, and n is an integer in a range of from 1 to 2).

2. The etchant composition according to claim 1, wherein the inorganic acid is any one selected from the group consisting of sulfuric acid, phosphoric acid, and a mixture thereof.

3. The etchant composition according to claim 1, wherein the inorganic acid is comprised in an amount of 81% to 95% by weight with respect to the total weight of the etchant composition.

4. The etchant composition according to claim 1, wherein the oxidizing agent is one selected from the group consisting of hydrogen peroxide, nitric acid, tert-butylhydroperoxide, and 2-butaneperoxide.

5. The etchant composition according to claim 1, wherein the oxidizing agent is comprised in an amount of 0.1% to 3% by weight with respect to the total weight of the etchant composition.

6. The etchant composition according to claim 1, wherein the additive represented by Formula 1 is an alkylammonium salt comprising a cationic surfactant or an alkyl alcohol ammonium salt comprising a cationic surfactant.

7. The etchant composition according to claim 1, wherein the additive represented by Formula 1 is an alkylsulfate salt comprising an anionic surfactant.

8. The etchant composition according to claim 1, wherein the additive represented by Formula 1 is comprised in an amount of 0.002% to 0.05% by weight with respect to the total weight of the etchant composition.

9. The etchant composition according to claim 1, the composition comprises 81% to 95% by weight of the inorganic acid, 0.1% to 3% by weight of the oxidizing agent, 0.002% to 0.05% by weight of the additive represented by Formula, and the remaining proportion of the water.

10. The etchant composition according to claim 1, wherein according to a structure of a cation and an anion contained in the additive represented by Formula 1, an etching selectivity of a titanium nitride film with respect to a tungsten film is adjusted in a range of 1 to 15.

11. A method of etching a structure in which a titanium nitride film and a tungsten film are stacked using the etchant composition of claim 1.

12. The method according to claim 11, wherein the etching of the structure in which the titanium nitride film and the tungsten film are stacked is performed at a temperature in a range of 50° C. to 90° C.

13. The method according to claim 12, wherein the etching of the structure in which the titanium nitride film and the tungsten film are stacked is performed by mixing the inorganic acid and the remaining components of the etchant solution in an etching facility.
